(19) United States
(12) Patent Application Publication
(10) Pub. No.: US 2003/0108672 A1
(43) Pub. Date: Jun. 12, 2003

(54) Method and device for synthesizing diamond

(75) Inventor: Yoshiki Takagi, Tokyo (JP)

Correspondence Address: KANESAKA AND TAKEUCHI, 1423 Powhatan Street, Alexandria, VA, 22314, US

(73) Assignee: NIPPON SHEET GLASS CO., LTD.

(21) Appl. No.: 10/267,742

(22) Filed: Oct. 10, 2002

Related U.S. Application Data
(63) Continuation of application No. PCT/JP01/03337, filed on Apr. 19, 2001.

(30) Foreign Application Priority Data
Apr. 21, 2000 (JP) 2000-121285

(51) Int. Cl. C23C 16/27

(52) U.S. Cl. 427/249.8; 118/666; 118/712; 118/713; 118/723 VE

(57) ABSTRACT

A thin film of synthesized diamond is formed on an amorphous substrate such as of glass. The device has a hermetically sealable chamber 1, solid carbon 4 disposed in the chamber 1, an electricity applying device 5 for applying electricity to the solid carbon 4 for heating the same, a substrate 8 disposed in the chamber 1, and a device 10 for feeding hydrogen into the chamber 1 to produce a predetermined pressure therein. With a low pressure of hydrogen atmosphere established in the chamber 1, application of electricity to the solid carbon 4 to increase its temperature to 2000-2300° C. results in formation of a thin film of diamond on the substrate 8.

### CROSS REFERENCE TO RELATED APPLICATION

This is a continuation application of PCT/JP01/03337 filed on Apr. 19, 2001.

### FIELD OF THE INVENTION

The present invention relates to a method and a device for synthesizing diamond, and particularly to a method and a device being capable for forming a thin film of synthesized diamond on an amorphous substrate such as a glass substrate.

### BACKGROUND OF THE INVENTION

Since diamond has excellent wear resistance, high hardness, and high thermal conductivity, the diamond is used as various functional materials. For example, due to its wear resistance and high hardness, diamond is used as a material of a machining tool or a cutting tool. For the high thermal conductivity, diamond is used as a material of a heat sink. Diamond is also used as a material of an electronic device for its semiconducting properties.

As a method for forming a thin film of synthesized diamond on a substrate, vapor phase synthesizing method is known in the art. The conventional vapor phase synthesizing method for forming a thin film of synthesized diamond is of a so-called “flow system” in which a raw gas is introduced into a reaction chamber and a reacted gas is flown out of the reaction chamber simultaneously. According to this method, a thin film of synthesized diamond can be formed only on a substrate which has an excellent property to grow diamond thereon. This is because the gas flows so fast that diamond is prevented to be synthesized stably.

Examples of the material of such a substrate allowing a thin film of synthesized diamond to be formed thereon by the conventional synthesizing method are semiconductors such as silicon, metals such as molybdenum and tungsten, and single crystal such as a sapphire. A thin film of synthesized diamond can not be formed on an amorphous substrate such as of glass or a ceramic substrate according to the conventional method.

Glass finds wide application as optical materials. If a diamond thin film is synthesized on a glass substrate, the diamond thin film may serve as a protective film which can exhibit significantly excellent protective effect because of its wear resistance, so that articles such as lens consisting of the glass will be widely used. A thermal conductivity of the glass having the diamond thin film thereon may be increased remarkably, so that a plate consisting of the glass may be widely used as a display panel of a liquid crystal display device having a high integration degree.

### SUMMARY OF THE INVENTION

It is an object of the present invention to provide a method and a device for synthesizing a synthesized diamond thin film on a substrate which is made of a variety of materials including an amorphous material such as glass.

A method for synthesizing diamond of the present invention comprises: a step of disposing solid carbon and a substrate in a hermetically sealable chamber, a step of establishing hydrogen atmosphere inside the chamber, and a step of applying electricity to the solid carbon to deposit diamond onto the substrate.

A diamond synthesizing device of the present invention comprises: a hermetically sealable chamber, solid carbon disposed in the chamber, an electricity applying device for applying electricity to the solid carbon to heat the same, a substrate disposed in the chamber, and a device for feeding hydrogen into the chamber to produce a predetermined pressure therein.

In the present invention, a thin film of diamond is synthesized in a completely sealed system which requires neither the introduction of raw gas nor discharge of reacted gas. The thin film of synthesized diamond can be formed on an amorphous substrate such as of glass.

The thin film of synthesized diamond can be formed on a substrate which may have a variety of shapes.

In the method of the present invention, carbon vaporized from the solid carbon by thermal energy reacts with hydrogen (or active species thereof) in the atmosphere so as to produce diamond on a surface of the substrate. There is a possibility of making synthesized artificial diamond having semiconducting properties by previously adding suitable additive elements to the carbon source as material.

The diamond synthesized by the method of the present invention using the sealed system has crystals of which crystal shape is sharp as compared to that of diamond synthesized by the conventional flow system using a heat filament. By the method of the present invention, a thin film of single crystal of diamond can be formed.

### BRIEF DESCRIPTION OF THE DRAWING

FIG. 1 is a vertical sectional view schematically showing an embodiment of a diamond synthesizing device of the present invention.

### DESCRIPTION OF THE PREFERRED EMBODIMENT

In the present invention, the carbon source may be graphite, glassy carbon, etc. The following description will be made as regard to an example using graphite.

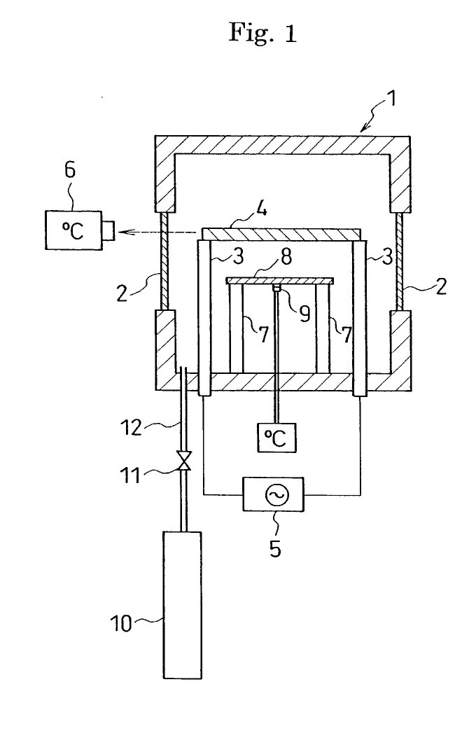

The device shown in FIG. 1 has a hermetically sealable chamber 1 having a sightglass 2 made of transparent silica glass, and a pair of rod supporting members 3, 3 standing within the chamber 1. The rod supporting members 3, 3 also serve as electricity applying terminals. A graphite rod 4 is placed on the rod supporting members 3 and 3 to extend therebetween. Electricity is applied from an electricity source 5 to the rod supporting members 3, 3 so as to heat the graphite rod 4 and to increase its temperature. The temperature of the graphite rod 4 is detected by a radiation thermometer (pyrometer) 6 disposed outside the sightglass 2. In the chamber 1, substrate supporting members 7, 7 are disposed to stand and a substrate 8 is placed on the plate supporting members 7 and 7 to extend therebetween so that the substrate 8 is disposed below and spaced apart from the graphite rod 4 by a predetermined distance. The temperature of the substrate 8 is detected by a thermocouple 9.

The distance between the substrate 8 and the graphite rod 4 depends on the size of the device as a whole and is generally in the order of 2 to 10 mm.

To establish hydrogen atmosphere at a predetermined pressure in the chamber 1, hydrogen gas can be supplied into the chamber 1 from a hydrogen gas cylinder 10 through a valve 11 and a pipe 12. An evacuator (not shown) is connected to the chamber 1 in order to evacuate air from the chamber 1. A pressure sensor (not shown) is also mounted in the chamber 1.

First, air in the chamber 1 is evacuated by the evacuator. It is preferable to evacuate air until the inner pressure of the chamber becomes 13 Pa (0.1 Torr) or less. Then, the valve 11 is opened to introduce hydrogen gas from the hydrogen gas cylinder 10 into the chamber 1. After establishing hydrogen atmosphere preferably at a pressure of 4.0 kPa to 66.7 kPa (30-500 Torr) in the chamber 1, all valves communicating with the chamber 1 are closed. After that, electricity is applied to the graphite rod 4 to increase the temperature of the graphite rod 4 to preferably 2000-2300° C. As a result of this, at least a part of carbon vaporized from the graphite rod 4 reacts with hydrogen or active species thereof in the atmosphere and reaches the neighborhood of the substrate 8. Subsequently, hydrogen is dissociated, whereby the carbon is deposited as diamond on the substrate 8.

The substrate 8 is heated by radiant heat from the graphite rod 4 to the order of 350-850° C. If necessary, a heater or cooling device (for example, a water-cooling pipe) may be disposed to control the temperature of the substrate 8. The substrate 8 may be disposed above or on a side of the graphite rod 4.

The time required to synthesize a diamond thin film is preferably on the order of 5-120 minutes. Increase in the synthesizing time leads to the increase in area where the film is formed and also leads to the increase in thickness of the film.

It should be noted that the substrate 8 may be disposed on a turn table. In this case, the substrate 8 may be rotated during the synthesis of diamond.

Without further elaboration, it is believed that one skilled in the art, using the preceding description, can utilize the present invention to its fullest extent. The following embodiments are, therefore, to be construed as merely illustrative, and not limitative in any way whatsoever, of the remainder of the disclosure.

The present invention is further illustrated by the following Examples.

### EXAMPLE 1

A diamond thin film was synthesized by using an amorphous silica glass plate as the substrate, by the device shown in FIG. 1, under the following conditions.

### Conditions for Synthesis

| | |
|---|---|
| Initial decompression: | 13 Pa (0.1 Torr) |
| Hydrogen gas pressure: | 6.7 kPa (50 Torr) |
| Substrate temperature: | 750° C. |
| Applied electric power: | 400-450 W |
| Graphite rod temperature: | 2000° C. |
| Distance between substrate and graphite rod: | 3 mm |
| Synthesizing time: | 40 minutes |

As a result of this, a synthesized diamond thin film as shown in Table 1 was formed on the substrate.

### EXAMPLE 2

A diamond thin film was synthesized in the same manner as Example 1 except that the synthesizing time was 60 minutes. As a result of this, a diamond thin film as shown in Table 1 was synthesized.

### EXAMPLE 3

A diamond thin film was synthesized in the same manner as Example 1 except that the substrate was an alumina ceramic plate, the temperature of graphite rod was 2300° C., and the synthesizing time was 60 minutes. As a result of this, a diamond thin film as shown in Table 1 was synthesized.

### EXAMPLE 4

A diamond thin film was synthesized in the same manner as Example 1 except that the substrate was a sapphire plate and that the temperature of graphite rod was 2300° C. As a result of this, a diamond thin film as shown in Table 1 was synthesized.

### EXAMPLE 5

A diamond thin film was synthesized in the same manner as Example 1 except that the substrate was a silicon plate and was rotated by a turn table at 30 rpm, the hydrogen gas pressure was 12 kPa (90 Torr), and the synthesizing time was 60 minutes. As a result of this, a diamond thin film as shown in Table 1 was synthesized.

The diamond thin films synthesized in the above Examples 1-5 were evaluated by measuring their Raman spectra. Raman spectroscopy indicated that all of Examples 1-5 had peak weave numbers on the order of 1330 cm⁻¹, characteristic of diamond. This value confirmed that the synthesized films were diamond comprising crystals of high quality with little secondary growth facets.

TABLE 1

| | Example 1 | Example 2 | Example 3 | Example 4 | Example 5 |
|---|---|---|---|---|---|
| Substrate | silica glass | silica glass | alumina | sapphire | silicon |
| | | | ceramic | | |
| Temperature | 2000 | 2000 | 2300 | 2000 | 2000 |
| of graphite | | | | | |
| rod (° C.) | | | | | |
| Synthesizing | 40 | 60 | 60 | 40 | 60 |
| time | | | | | |
| (minutes) | | | | | |
| Synthesized | | | | | |
| diamond | | | | | |
| thin film | | | | | |
| Crystal size | 0.1 ˜ 5 | 3 ˜ 4 | about 5 | 0.1 ˜ 3 | 1 ˜ 5 |
| (μm) | | | | | |
| Film | 1 ˜ 5 | 3 ˜ 4 | about 5 | 1 ˜ 3 | 1 ˜ 5 |
| thickness | | | | | |
| (μm) | | | | | |
| Forming area | about 1.0 | about 1.0 | about 1.0 | about 1.0 | about 1.0 |
| (cm²) | | | | | |
| Raman | about | about | about | about | about |
| Spectrum | 1330 | 1330 | 1330 | 1330 | 1330 |
| Absorption | | | | | |
| wavelength | | | | | |
| (cm⁻¹) | | | | | |

### Industrial Applicability

As described above, according to the present invention, a synthesized diamond thin film can be formed on a substrate which may be made of a variety of materials including an amorphous material such as glass and may have a variety of shapes.

The foregoing is considered illustrative only of the principles of the invention. Further, since numerous modifications and changes will readily occur to those skilled in the art, it is not desired to limit the invention to the exact construction and operation shown and described. Accordingly, all suitable modifications and equivalents may be resorted to that fall within the scope of the invention and the appended claims.

What is claimed is:

1. A method for synthesizing diamond with using a hermetically sealable chamber in which solid carbon and a substrate consisted of a material except for silicon are disposed, comprising:
a step of establishing hydrogen atmosphere inside said chamber; and
a step of applying electricity to said solid carbon to increase the temperature of the same so as to vaporize carbon and deposit the vaporized carbon as diamond onto said substrate.

2. A method for synthesizing diamond as claimed in claim 1, wherein the temperature of said solid carbon is increased to 2000-2300° C.

3. A method for synthesizing diamond as claimed in claim 1, wherein the pressure of the hydrogen atmosphere in said chamber is set at 4.0-66.7 kPa.

4. A method for synthesizing diamond as claimed in claim 1, wherein the temperature of said substrate is set at 350-850° C.

5. A method for synthesizing diamond as claimed in claim 1, wherein the spacing between said substrate and said solid carbon is 2-10 mm.

6. A method for synthesizing diamond as claimed in claim 1, wherein the carbon vaporized from said solid carbon reacts with hydrogen or active species thereof in the atmosphere and reaches the neighborhood of said substrate, and subsequently the hydrogen is dissociated, whereby the carbon is deposited as diamond on said substrate.

7. A method for synthesizing diamond as claimed in claim 1, wherein the synthesizing time is 5-120 minutes.

8. A method for synthesizing diamond as claimed in claim 1, wherein said substrate is an amorphous substrate.

9. A method for synthesizing diamond as claimed in claim 8, wherein said substrate is a glass substrate.

10. A method for synthesizing diamond as claimed in claim 1, wherein said substrate is rotated.

11. A diamond synthesizing device comprising:
a hermetically sealable chamber;
solid carbon disposed in said chamber;
an electricity applyer for applying electricity to said solid carbon to heat said solid carbon;
a substrate consisted of a material except for silicon and disposed in said chamber; and
a feeder for feeding hydrogen into said chamber to produce a predetermined pressure therein.

12. A diamond synthesizing device as claimed in claim 11, wherein said chamber has a transparent sightglass, and a radiation thermometer for measuring the temperature of said solid carbon is disposed outside said sightglass.

13. A diamond synthesizing device as claimed in claim 11, wherein the spacing between said substrate and said solid carbon is 2-10 mm.

14. A diamond synthesizing device as claimed in claim 11, further comprising a rotary unit for rotating said substrate.

15. A method for synthesizing diamond as claimed in claim 1, wherein said substrate is a ceramic substrate.

16. A method for synthesizing diamond as claimed in claim 15, wherein said substrate is rotated.
